(19) United States
(12) Patent Application Publication
(10) Pub. No.: US 2018/0205221 A1
(43) Pub. Date: Jul. 19, 2018

(54) CIRCUIT ASSEMBLY FOR ELECTRONICALLY ACTUATING TRIGGERABLE SURGE ARRESTERS

(71) Applicant: DEHN + SÖHNE GMBH + CO. KG, Neumarkt/Opf. (DE)

(72) Inventors: Thomas Böhm, Hohenfels (DE); Johannes Spies, Neumarkt (DE); Franz Schork, Nürnberg (DE); Ralph Brocke, ILMENAU/OBERPÖRLITZ (DE)

(21) Appl. No.: 15/742,745

(22) PCT Filed: Jun. 16, 2016
(86) PCT No.: PCT/EP2016/063813

§ 371 Date: Jan. 8, 2018

(30) Foreign Application Priority Data
Jul. 27, 2015 (DE) 10 2015 009 771.7
Oct. 13, 2015 (DE) 10 2015 013 222.9

(51) Int. Cl. H02H 9/00; H02H 9/06; H02H 1/00; H03K 5/24; H01T 2/02

(52) U.S. Cl. CPC H02H 9/005; H02H 9/06; H01T 2/02; H03K 5/24; H02H 1/0007

(57) ABSTRACT

The invention relates to a circuit assembly for electronically actuating triggerable surge arresters, such as spark gaps, multi-electrode gas arresters, or similar means. At least one power semiconductor is activated by a switching stage upon detecting a surge event, and the output side of the power semiconductor is connected to a trigger input of the surge arrester. According to the invention, the switching stage is designed as a control and analysis unit for detecting transient surge events and has first a pulse detection stage which allows a detection of pulses in a level-sensitive or increase rate-dependent manner and second a microcontroller or similar means for evaluating events. The output side of the microcontroller leads to the control input of the power semiconductor, and a quick-switching rectifier is provided between the output of the power semiconductor and the trigger input of the surge arrester.

The invention relates to a circuit assembly for electronically actuating triggerable surge arresters, such as spark gaps, multi-electrode gas arresters, or similar means, wherein at least one power semiconductor is activated by a switching stage upon detecting a surge event, and the output side of the power semiconductor is connected to a trigger input of the surge arrester, according to claim 1.

For dissipating high pulse currents, in particular in the case of direct lightning strikes, it is known to use overvoltage protection components, typically surge arresters on the basis of spark gap technology or else gas arresters. A disadvantage is the response voltage that is usually high in spark gaps, since the applied overvoltage is first required to cause a flashover and ionization between the electrodes of the spark gaps, and, after that, a response that is dependent on the increase rate of voltage occurs, which leads to higher protective levels in case of high increase rates. For this reason, trigger circuits have been proposed which enable lower protective levels, such as e.g. 1.5 kV for devices in the 230 V network. Usual trigger circuits are composed of varistors, gas discharge arresters, suppressor diodes or capacitances and produce a trigger signal which will be supplied to a corresponding trigger electrode of a spark gap and ignite the same reliably.

Constructive measures succeeded in developing spark gaps which already have an improved response behavior and, by connecting a downstream deion chamber, can be realized to be virtually non-blowing out.

Reference should be made in this respect to DE 10 2011 102 257 A1 which discloses a horn spark gap with a deion chamber of a non-blowout design having a multi-part housing of insulating material as a supporting and accommodating body for the horn electrodes. According to the solution therein, the arc travel path between the electrodes is delimited in the direction of the deion chamber by a plate-shaped insulating material, wherein the plate-shaped insulating material is inserted in respective shaped portions in the half-shell in a form-fitting manner. In addition, a ferromagnetic deposit is provided for influencing the arc travel. Furthermore, there are means for influencing the gas flow within the horn spark gap and improving the operating behavior of such a surge arrester.

From WO 2012/022547 A1, an arrangement for igniting spark gaps by means of an insulated trigger electrode is already known, wherein the trigger electrode is connected to one of the other main electrodes via at least one voltage-switching or voltage-monitoring element, and there is an air gap between the trigger electrode and the further main electrode. According to the solution therein, the trigger electrode forms a sandwich structure with the insulation section and a layer of a material having a lower conductivity than the material of one of the main electrodes. The sandwich structure represents a layered dielectric in the series connection of a first partial capacitor with the dielectric of the insulation section and a second partial capacitor with the material as dielectric. Such a solution allows protection levels in the range of 1.5 kV for 230/400 V low-voltage networks to be achieved.

However, it has turned out for many topical cases of application that the hitherto existing protective levels are not sufficient, whereby a risk for downstream electronic components cannot be excluded.

From the aforementioned, it is therefore a task of the invention to propose a further developed circuits assembly for electronically actuating triggerable surge arresters, such as spark gaps or multi-electrode gas arresters, wherein significantly lower protective levels should be achieved than has hitherto been the case. Moreover, it should be ensured for the circuit assembly to be insensitive with respect to the phase-to-phase main voltage, and a direct use at different main voltages should be possible. Moreover, an approach should be created that guarantees a monitoring and/or diagnosing of the operating behavior and thus of the loads of the respective employed surge arrester.

The circuit assembly should be realized such as to be principally suitable for actuating spark gaps but also multi-electrode gas arresters.

The solution of the inventive task is performed by the feature combination according to claim 1, with the dependent claims comprising at least appropriate configurations and further developments.

Accordingly, a circuit assembly for electronically actuating triggerable surge arresters is taken as a basis. These surge arresters may be spark gaps, in particular horn spark gaps, but also multi-electrode gas arresters or similar means.

The circuit assembly comprises at least one power semiconductor which is activated by a switching stage upon detecting a surge event. The output side of the power semiconductor is connected to a or the respective trigger input of the employed surge arrester.

According to the invention, the switching stage is designed as a control and analysis unit for detecting transient surge events. For this purpose, the control and analysis unit has first a pulse detection stage which allows pulses to be detected in a level-sensitive or increase rate-dependent manner. Secondly, an analysis or control unit, in particular a microcontroller is provided for evaluating events, wherein the output side of the microcontroller leads to the control input of the power semiconductor.

A quick-switching rectifier is provided between the output of the power semiconductor and the trigger input of the surge arrester so as to be able to control surges of different polarities.

The use of the quick-switching rectifier simplifies the assembly since only one relatively cost-intensive power semiconductor needs to be introduced.

In an embodiment of the invention, the pulse detection stage leads directly to the control input of the power semiconductor for preventing the actuating of the surge arrester from being delayed. For the same purpose, a clamping operation of the power semiconductor may be provided.

After the desired quick actuating of the power semiconductor in the range of substantially less than 50 ns, the microcontroller of the control and analysis unit takes over and defines the further operation in which a reliable ignition of the surge arrester and a subsequent time-controlled disconnecting of the trigger path are performed or take place.

In an embodiment of the invention which is in particular appropriate for the use of the circuit assembly in case of multi-electrode gas arresters as surge arresters, a transmitter or transformer is inserted between the output of the power semiconductor and the trigger input.

IGBTs or MOSFETs are preferably used as power semiconductors.

In a further development of the invention, in particular for the intended purpose of diagnosing and state monitoring the circuit assembly and for analyzing the load situation of a connected surge arrester, respectively, the microcontroller comprises a unit for storing and/or displaying surge events that induced triggering.

The signal values, at which the control and analysis unit responds, may either be predefined by the manufacturer or else be set externally, in particular be programmed via the microcontroller.

In one embodiment of the invention, the pulse detection stage is composed of a series connection of suppressor diodes connected to the network, wherein upon exceeding the clamping voltage at a first one of the suppressor diodes, a signal level is generated which reaches the microcontroller so as to provide or trigger a trigger signal after the assessment of significance.

In a further optional embodiment, the pulse detection stage has a high pass with suppressor diodes which is connected to the network, wherein the high pass is configured by an associated resistor and capacitor such that, at a predefined increase rate of a voltage level, a comparator input of the microcontroller detects a signal level which is trigger-relevant.

A minimum level above the mains voltage may be predefined by means of a suppressor diode in the high pass branch of the pulse detection stage for the further detection and evaluation.

The invention will be explained below in more detail on the basis of exemplary embodiments and with reference to Figures.

Shown are in:

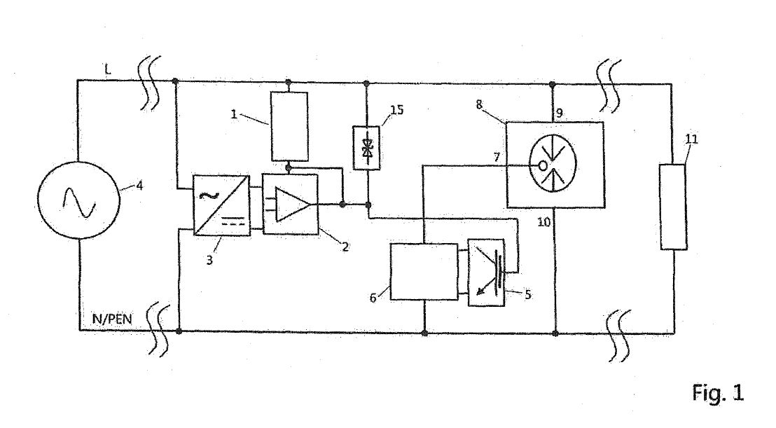

FIG. 1 a block diagram of the solution according to the invention, in particular provided for being used in a spark gap with a trigger input;

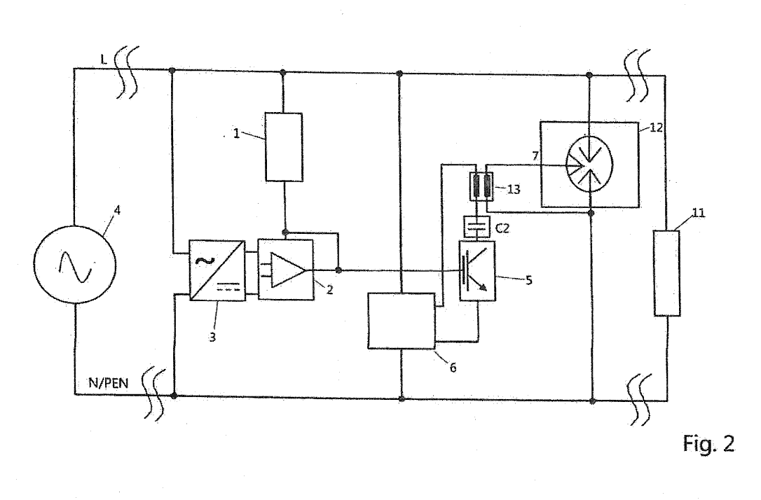

FIG. 2 a block diagram of the solution according to the invention, in particular designed for being used in a three-electrode gas arrester as the surge arrester, and

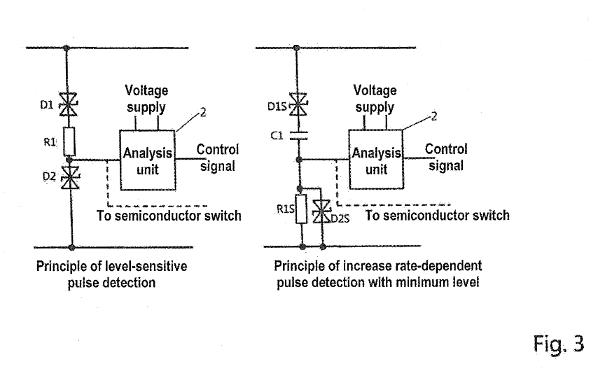

FIG. 3 a schematic diagram of the level-sensitive pulse detection (left-hand diagram) as well as an increase rate-dependent pulse detection with minimum level (right-hand diagram).

The circuit assembly illustrated in the Figures is realized as an active circuit composed of quick-switching semiconductor devices which are connected to the trigger input of the respective surge arrester. The respective semiconductor devices or power semiconductors are operated via a control and analysis unit. The control and analysis unit comprises a pulse detection stage 1 and a microcontroller 2. The microcontroller 2 is coupled to a voltage supply 3 which is connected to the low-voltage network 4.

At the output side, the microcontroller 2 is connected to the control input of a semiconductor switch 5.

According to FIG. 1, the semiconductor switch 5 is connected to the trigger input 7 of the spark gap 8 via an assembly 6 for pulse rectification which acts as a quick-switching rectifier.

The main electrodes 9 and 10 of the spark gap 8 are likewise coupled to the network 4 and are connected to the load 11 to be protected.

In the embodiment according to FIG. 2, a three-electrode gas arrester 12 likewise comprising a trigger terminal 7 is employed as the surge arrester. In addition, a transducer 13 is provided in this embodiment.

The voltage supply 3 which is connected to the supply network 4 provides the necessary operating voltage for the assembly. The voltage supply 3 is in this case realized to be pulse-resistant and ensures that functional impairment is not given during transient events, i.e. during the response and arresting of the spark gap and in the case of phase-to-phase voltage.

With the occurrence of a transient event, the microcontroller 2 is driven via the pulse detection circuit 1. The pulse detection circuit is realized, as is symbolically shown in FIG. 3, either as a series connection of suppressor diodes D1 and D2 for the level-sensitive pulse detection (left-hand illustration) or as a high pass for the increase rate-sensitive pulse detection (right-hand illustration).

At the collector of the semiconductor switch 5 according to FIG. 2, a capacitor C2 is connected in the primary circuit of the transducer 13 in order to delimit a line follow current. The capacitance C2 is quickly discharged by a discharging circuit after triggering so that a recurring triggering or the restoring of the operational readiness is possible within a very short time.

It should be noticed at this point that there is the option in principle to integrate the power semiconductor(s) including the rectifier circuit along with the analysis and control unit mechanically in a common housing so that a space-saving assembly can be created that requires little installation space.

In the configuration of the series connection according to FIG. 3, a high level is generated at the input of the microcontroller 2 while using the diodes D1, D2 and R1 (left-hand illustration) after the clamping voltage of diode D1 had been exceeded.

In the variant including the high pass (right-hand illustration), the microcontroller 2 is dimensioned via the elements C1 and R1 such that, as of a certain increase rate of voltage; an input of the microcontroller detects a high level via the comparator provided there. This naturally takes only place at levels above the mains voltage, which can be set by the diode D1S.

It has been shown that, despite only few computational operations, delay times occur in usual 8-bit microcontrollers which result in a degraded protective level due to the signal pass times and thus a delayed switching of the trigger current.

According to the invention, this can be prevented by guiding the signal of the overvoltage detection directly to the driver in the microcontroller 2 or directly to the power semiconductor 5. This allows a very fast actuation in the range of less than 50 ns.

In the case of very steep slopes, it is advantageous for a further reduction of the turn-on time of the power semiconductors to power them in the active clamping operation symbolized by the constructional unit 15.

A first trigger current is already conducted very quickly into the spark gap due to these kinds of pre-control.

With consideration of the processing time, the microcontroller 2 then tales over the further control and the appropriate operation. First, the microcontroller 2 switches on the corresponding power semiconductor 5 until the reliable arcing of the spark gap 8 or the three-electrode gas arrester 12. Thereafter, the trigger path is turned off in a time-controlled manner so that a possible line follow current will not flow through the trigger path. After that, the entire trigger circuit is again ready for operation.

The solution according to the invention enables protective levels below 1 kV at a desired TOV resistance. The very pulse detection may then be performed in a progressive manner, whereby various nominal voltages and a protective level adapted thereto are possible. A setting may be predefined by the manufacturer but may also be performed by a pre-setting in terms of a programming of the controller.

The pulse rectification 6 provided leads to a saving of power semiconductors, which decreases both the space requirement of the circuit and the costs thereof.

A basic protection and a basic function of the circuit assembly is guaranteed even with no operating voltage being applied, since the spark gap is able to ignite virtually overhead by the active clamping operation mode of the semiconductor switch or power semiconductor.

Of course, several semiconductor elements may also be connected in parallel and powered by a single control circuit to reach higher trigger current values. Due to the rectification, the design as a bipolar circuit assembly is omitted. In order to achieve fast switching times, discrete, fast IGBT diodes may be used.

According to the invention, a trigger current detection is possible by using the microcontroller 2 as an operation counter or for diagnostic purposes. A corresponding display may be guided to the outside in terms of response detection.

Moreover, the discharged current of the surge arrester after triggering may be monitored, signalized and stored by means of the microcontroller. In this respect, shunts, Hall elements or similar may be used in a known way.

1. Circuit assembly for electronically actuating triggerable surge arresters, such as spark gaps (8), multi-electrode gas arresters (12), or similar means, wherein at least one power semiconductor (5) is activated by a switching stage upon detecting a surge event, and the output side of the power semiconductor (5) is connected to a trigger input (7) of the surge arrester,
characterized in that
the switching stage is designed as a control and analysis unit for detecting transient surge events first has a pulse detection stage (1) which allows pulses to be detected in a level-sensitive or increase rate-dependent manner, furthermore secondly comprises a microcontroller (2) or similar means for evaluating events, wherein the output side of the microcontroller (2) leads to the control input of the power semiconductor (5), and a quick-switching rectifier (6) is provided between the output of the power semiconductor (5) and the trigger input (7) of the surge arrester (8; 12).

2. Circuit assembly according to claim 1,
characterized in that
the pulse detection stage (1) leads directly to the control input of the power semiconductor (5) and/or a clamping operation (15) of the power semiconductor (5) is provided for preventing the actuating of the surge arrester (8; 12) from being delayed.

3. Circuit assembly according to claim 2,
characterized in that
after a quick actuating of the power semiconductor (5) in the range of substantially less than 50 ns, the microcontroller (2) of the control and analysis unit defines the further operation in which a reliable arcing of the surge arrester (8; 12) and a subsequent time-controlled disconnecting of the trigger path (5; 6) are performed.

4. Circuit assembly according to claim 1,
characterized in that
a transducer (13) is provided between the output of the power semiconductor (5) and the trigger input (7).

5. Circuit assembly according to claim 1,
characterized in that
the power semiconductor (5) is realized as an IGBT, a MosFET or a fast-switching thyristor.

6. Circuit assembly according to claim 1,
characterized in that
the microcontroller (2) comprises a unit for storing and/or displaying surge events that induced triggering.

7. Circuit assembly according to claim 1,
characterized in that
the response voltage of the control and analysis unit is definable or settable.

8. Circuit assembly according to claim 1,
characterized in that
the pulse detection stage (1) comprises a series connection of suppressor diodes (D1, D2) connected to the network, wherein upon exceeding the clamping voltage at a first one of the suppressor diodes (D1), a signal level is generated which reaches the microcontroller (2).

9. Circuit assembly according to claim 1,
characterized in that
the pulse detection stage (1) has a high pass with suppressor diodes (D1S and D2S) which is connected to the network, wherein the high pass is configured by means of a resistor (R1S) and a capacitor (C1) such that, at a predefined increase rate of a voltage level, a comparator of the microcontroller (2) detects a signal level which is trigger-relevant.

10. Circuit assembly according to claim 9,
characterized in that
a minimum level above the mains voltage may be predefined by means of a suppressor diode (D1S) in the high pass branch.
